(19) United States
(12) Patent Application Publication
(10) Pub. No.: US 2023/0288262 A1
(43) Pub. Date: Sep. 14, 2023

(54) BOLOMETER MATERIAL, INFRARED SENSOR AND METHOD FOR MANUFACTURING SAME

(71) Applicant: NEC Corporation, Minato-ku, Tokyo (JP)

(72) Inventors: Ryota YUGE, Tokyo (JP); Tomo TANAKA, Tokyo (JP)

(73) Assignee: NEC Corporation, Minato-ku, Tokyo (JP)

(21) Appl. No.: 17/927,233

(22) PCT Filed: May 25, 2021
(86) PCT No.: PCT/JP2021/019796

§ 371 Date: Nov. 22, 2022

(30) Foreign Application Priority Data
May 26, 2020 (WO) PCT/JP2020/020795
Dec. 28, 2020 (JP) 2020-218851

(51) Int. Cl. G01J 5/20; H01L 31/0352; H01L 31/09

(52) U.S. Cl. CPC G01J 5/20; H01L 31/035227; H01L 31/09; G01J 2005/202

(57) ABSTRACT

An object of the present invention is to provide a bolometer thin film and an infrared sensor having a high TCR value, and a method for manufacturing the same. According to the present invention, a bolometer material which is a thin film comprising semiconducting carbon nanotubes and a negative thermal expansion material, and an infrared sensor comprising the bolometer material are provided.

### TECHNICAL FIELD

The present invention relates to a bolometer material, an infrared sensor, and a method for manufacturing the same.

### BACKGROUND ART

Infrared sensors have a very wide range of applications such as not only monitoring cameras for security, but also thermography for human body, in-vehicle cameras, and inspection of structures, foods, and the like, and are thus actively used in industrial applications in recent years. In particular, development of a low-cost and high-performance uncooled infrared sensor capable of obtaining biological information in cooperation with IoT (Internet of Things) is expected. In conventional uncooled infrared sensors, VOₓ (vanadium oxide) has been mainly used in the bolometer unit, but high process cost because of the necessity of heat treatment under vacuum, and low temperature coefficient resistance (TCR) (about −2.0%/K) are problems.

For TCR improvement, a material that has a large resistivity change with respect to temperature increase, and also has a high conductivity, and therefore, semiconducting single-walled carbon nanotubes having a large band gap and carrier mobility are expected to be applied to the bolometer unit. In addition, since carbon nanotubes are chemically stable, an inexpensive device manufacturing processes such as a printing technique can be applied, and there is a possibility that a low cost/high performance infrared sensor can be realized. However, single-walled carbon nanotubes typically contain nanotubes with semiconducting properties and nanotubes with metallic properties in a ratio of 2:1, and separation is thus required.

In addition, in order to further increase sensitivity, in addition to improving the band gap of carbon nanotubes, a structure and a conductive mechanism in which the resistivity reduction increases with temperature rising need to be achieved as a carbon nanotube thin film.

Patent Document 1 suggests applying typical single-walled carbon nanotubes to a bolometer unit, and producing a bolometer by a low-cost thin film process in which a dispersion liquid is prepared by mixing single-walled carbon nanotubes in an organic solvent utilizing their chemical stability and then is applied on an electrode. In this case, TCR is successfully improved to about −1.8%/K by subjecting single-walled carbon nanotubes to annealing treatment in the air.

In Patent Document 2, since metallic and semiconducting components are present in a mixed state in single-walled carbon nanotubes, semiconducting single-walled carbon nanotubes of uniform chirality are extracted using an ionic surfactant and applied to the bolometer unit, and TCR of −2.6%/K is thereby successfully achieved.

### CITATION LIST

### Patent Document

Patent Document 1: WO 2012/049801
Patent Document 2: Japanese Patent Laid-Open No. 2015-49207

### SUMMARY OF INVENTION

### Technical Problem

However, in the carbon nanotube thin film used for the infrared sensor described in Patent Document 1, since many metallic carbon nanotubes are present in a mixed state in carbon nanotubes, TCR is low at room temperature range and the improvement of the performance of the infrared sensor is limited. In addition, the TCR value of the infrared sensor using semiconducting carbon nanotubes described in Patent Document 2 cannot be said sufficient from the view point of high sensitivity, and further improvement of the carbon nanotube film is required.

In view of the above-described problems, an object of the present invention is to provide a bolometer material and an infrared sensor using semiconducting carbon nanotubes and having a high TCR value, and a method for manufacturing the same.

### Solution to Problem

According to an aspect of the present invention, there is provided a bolometer material which is a thin film comprising semiconducting carbon nanotubes and a negative thermal expansion material.

According to an aspect of the present invention, there is provided a method for manufacturing a bolometer material, comprising mixing carbon nanotubes, a nonionic surfactant, and a dispersion medium to prepare a solution comprising carbon nanotubes;
subjecting the solution to dispersion treatment to disperse and cut the carbon nanotubes, thereby preparing a carbon nanotube dispersion liquid;
subjecting the carbon nanotube dispersion liquid to free flow electrophoresis to separate semiconducting carbon nanotubes and metallic carbon nanotubes, thereby preparing a semiconducting carbon nanotube dispersion liquid comprising semiconducting carbon nanotubes; and
mixing the semiconducting carbon nanotube dispersion liquid and a negative thermal expansion material to prepare a mixed liquid,
removing excess nonionic surfactant and dispersion medium from the mixed liquid to form a thin film in a desired form.

According to an aspect of the present invention, there is provided a method for manufacturing an infrared sensor,

wherein the infrared sensor comprises
a substrate;
a first electrode on the substrate;
a second electrode spaced from the first electrode on the substrate; and
a bolometer material electrically connected with the first electrode and the second electrode, and
   wherein the method comprises
(a) applying a mixed liquid comprising semiconducting carbon nanotubes and a negative thermal expansion material on the substrate;
(b) subjecting the substrate on which the mixed liquid is applied to heat treatment; and
(c) producing the first electrode and the second electrode on the substrate before applying the mixed liquid on the substrate, or before or after subjecting the substrate on which the mixed liquid is applied to heat treatment,
   thereby connecting the first electrode and the second electrode by the bolometer material.

According to an aspect of the present invention, there is also provided an infrared sensor comprising
a substrate;
an infrared detection unit held on the substrate with a gap therebetween by a supporting leg,
wherein the infrared detection unit comprises a bolometer thin film comprising semiconducting carbon nanotubes and a negative thermal expansion material.

According to an aspect of the present invention, there is also provided an infrared sensor comprising
a substrate;
a heat insulating layer formed on the substrate; and
a bolometer thin film formed on the heat insulating layer;
   wherein the bolometer thin film comprises semiconducting carbon nanotubes and a negative thermal expansion material.

According to an aspect of the present invention, there is also provided a method for manufacturing an infrared sensor comprising
forming an infrared detection unit on a substrate via a supporting leg;
forming a gap between the substrate and the infrared detection unit; and
forming a bolometer thin film comprising semiconducting carbon nanotubes and a negative thermal expansion material on the infrared detection unit.

According to an aspect of the present invention, there is also provided a method for manufacturing an infrared sensor comprising
forming a heat insulating layer on a substrate, and
forming a thin film comprising semiconducting carbon nanotubes and a negative thermal expansion material on the insulating layer.

### Advantageous Effect of Invention

According to the present invention, a bolometer material, an infrared sensor, and an infrared sensor array having a high TCR value, and a method for manufacturing the same can be provided.

### BRIEF DESCRIPTION OF DRAWINGS

FIG. 1 is a schematic view of the bolometer thin film and the infrared sensor manufactured by the present invention (plane view).

FIG. 2 is a schematic view of the bolometer thin film manufactured by the present invention (three-dimensional view).

FIG. 3 is a perspective view of the bolometer element according to an embodiment of the present invention.

FIG. 4 is a vertical sectional front view showing the cell structure of the bolometer according to an embodiment of the present invention.

FIG. 5 is a vertical sectional front view showing the cell structure of the bolometer according to an embodiment of the present invention.

FIG. 6 is a vertical sectional front view showing the cell structure of the bolometer according to an embodiment of the present invention.

FIG. 7 is a plane view showing the structure of the bolometer array according to an embodiment of the present invention.

FIG. 8 is a vertical sectional front view showing the cell structure of the bolometer according to an embodiment of the present invention.

FIG. 9 is a vertical sectional front view showing the method for manufacturing a bolometer according to an embodiment of the present invention.

FIG. 10 is a process chart showing the method for manufacturing a bolometer array of an embodiment of the present invention.

FIG. 11 is a plane view showing the structure of a bolometer array according to an embodiment of the present invention.

FIG. 12 is a plane view showing the structure of a bolometer array according to an embodiment of the present invention.

FIG. 13A is a plane view showing the structure of a bolometer array according to an embodiment of the present invention.

FIG. 13B is a plane view showing the structure of a bolometer array according to an embodiment of the present invention.

FIG. 14 is an AFM images of the bolometer thin film in Examples.

FIG. 15 is a graph showing the TCR value of the infrared sensor in Examples.

### DESCRIPTION OF EMBODIMENTS

The inventor found that a high TCR value can be obtained by applying a thin film in which semiconducting carbon nanotubes and a negative thermal expansion material are mixed to a bolometer material.

The bolometer material according to the present embodiment is a carbon nanotube composite material in which a negative thermal expansion material is dispersed in a carbon nanotube aggregate formed by the aggregation of a plurality of semiconducting carbon nanotubes, wherein the carbon nanotube aggregate has a three-dimensional mesh structure that forms a network structure formed of dispersed carbon nanotubes intertwined with each other into an aggregate. In such a three-dimensional electrically conductive network formed of carbon nanotubes, the carbon nanotubes are not necessarily all connected to each other to contribute to electric conductivity in the bolometer material, but part of the carbon nanotubes does not contribute to the electrical conduction mechanism. These carbon nanotubes build a new electrically conductive path resulting from the effect of reduction in the volume of the negative thermal expansion material exhibited by an increase in temperature. Or, the effect of reduction in the volume further increases the contact area between the carbon nanotubes, and moreover, the number of electrically conductive paths also increases. As a result, a larger increase in current occurs as the temperature increases, resulting in an improvement in a TCR value. That is, the negative thermal expansion material mixed with the semiconducting carbon nanotubes shrinks as the temperature rises, creating an additional network of carbon nanotubes previously separate from each other, resulting in an increase in the number of electrically conductive paths, whereby a greater amount of current flows. Furthermore, in an embodiment, using a negative thermal expansion material having resistance greater than that of the semiconducting carbon nanotubes allows more efficient formation of electrically conductive paths formed of the semiconducting carbon nanotubes.

In addition, in an embodiment, it is preferable to apply a thin film in which carbon nanotubes having a predetermined diameter and length and a negative thermal expansion material to the bolometer material.

Furthermore, in an embodiment, it is also possible that the carbon nanotubes and the negative thermal expansion material forming the bolometer thin film are connected by molecular chains. This has the effects of reducing hysteresis upon temperature increase and decrease of the bolometer thin film, and improving durability.

Furthermore, in an embodiment, a TCR value and the structure can be controlled by combining negative thermal expansion materials having large and small thermal expansion coefficients, or having anisotropy and no anisotropy.

In an embodiment, it is also preferable to use a nonionic surfactant for the separation of semiconducting carbon nanotubes from untreated carbon nanotubes, and it is also preferable to use a nonionic surfactant having a long molecular length as the noninic surfactant. Such a nonionic surfactant has a weak interaction with the carbon nanotubes and can be easily removed after applying a dispersion liquid. Therefore, a stable carbon nanotube conductive network can be formed and an excellent TCR value can be obtained.

The bolometer thin film in which semiconducting carbon nanotubes and a negative thermal expansion material are mixed described above can be suitably used in a MEMS-type bolometer element, a printed-type bolometer element, or a bolometer array using thereof as described below. The bolometer film of the present embodiment has a high light absorption rate (infrared absorption rate). Therefore, in one embodiment, it is possible to simplify the manufacturing process and reduce the cost by omitting elements such as the light reflection layer and the infrared absorption layer in some cases.

The present invention has the characteristics as described above, and examples of embodiments will be described below.

In the following embodiments, a bolometer that detects infrared light (i.e., an infrared sensor) will be used as an example for explanation, but the bolometer of the present embodiment can also be used to detect, for example, terahertz waves in addition to infrared light. Therefore, as used herein, the terms “infrared ray” and “infrared light” can be read as appropriate for a desired electromagnetic wave to be detected. The bolometer of the present embodiment using a bolometer film comprising carbon nanotubes and a negative thermal expansion material can be particularly preferably used for detecting an electromagnetic wave having a wavelength of 0.7 pin to 1 mm. The electromagnetic waves included in this wavelength range include, in addition to infrared ray, terahertz wave.

The bolometer of the present embodiment is preferably an infrared sensor.

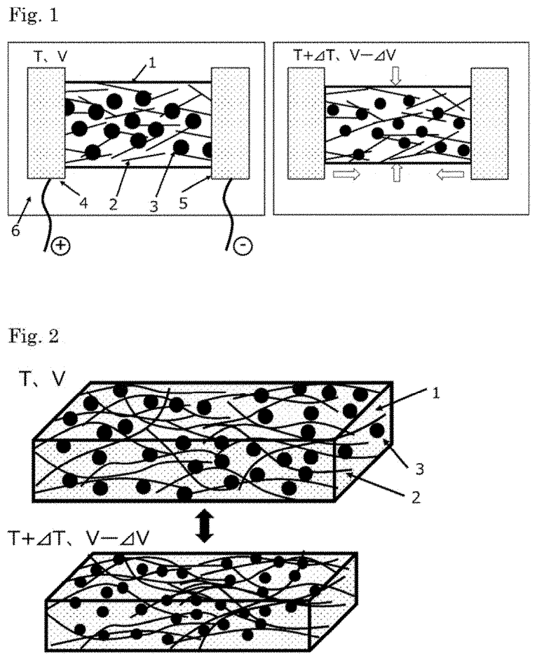

FIG. 1 is a schematic diagram of a bolometer material (bolometer thin film), and a detection unit of an infrared sensor of one embodiment of the present invention. Bolometer thin film 1 (FIG. 1: plane view, FIG. 2: three-dimensional view) comprises, in its inside, semiconducting carbon nanotubes 2 and negative thermal expansion material 3, which are dispersed and intertwined. The semiconducting carbon nanotubes 2 form a three-dimensional electrically conductive network. First electrode 4 and second electrode 2 are on substrate 6, wherein these electrodes are connected to each other by the bolometer thin film 1 present therebetween. As described later, the bolometer thin film 1 is mainly composed of, for example, a plurality of semiconducting carbon nanotubes separated using a non-ionic surfactant. The bolometer film decreases in the volume (V−ΔV) as the temperature rises (T+ΔT) and the negative thermal expansion material 5 shrinks. As a result, unconnected carbon nanotubes which were separated to each other and not electrically connected before the temperature rise build new electrically conductive paths, and the amount of the electrical flow is increased. In other word, the amount of electrical current of semiconducting carbon nanotubes typically increase exponentially as the temperature rises, but in the present embodiment, increase of conductive paths is further added, whereby a greater amount of electrical current flows. As a result, an extremely high TCR value can be realized.

The infrared sensor with the bolometer thin film 1 can be manufactured as described below. A dispersion liquid comprising semiconducting carbon nanotubes is applied on a substrate, dried and heat treated. Through these procedures, a bolometer thin film layer is formed on the substrate. Thereafter, a first and a second electrodes are produced by vapor deposition or application at an interval of 50 μm over the bolometer thin film. The obtained infrared sensor detection unit of FIG. 1 detects temperature by utilizing the temperature dependence of the electrical resistance caused by light irradiation. Therefore, it can also be used similarly in other frequency regions as long as the temperature changes by light irradiation, and for example, the terahertz region can also be detected. In addition, the detection of the change in electrical resistance caused by temperature change can also be performed not only by the structure of FIG. 1, but also by providing a gate electrode to form a field effect transistor and thereby amplifying the change in resistance value.

The infrared sensor with the bolometer thin film 1 can also be manufactured as follows. SiO₂-coated Si is used as a substrate, and is sequentially washed with acetone, isopropyl alcohol, and water, and is then subjected to oxygen plasma treatment to remove the organics and the like on the surface. Next, the substrate is immersed in an aqueous 3-aminopropyltriethoxysilane (APTES) solution, and dried. A mixed liquid is prepared with semiconducting carbon nanotubes dispersed in a polyoxyethylene alkyl ether solution such as polyoxyethylene (100) stearyl ether or polyoxyethylene (23) lauryl ether, which is a nonionic surfactant, and a negative thermal expansion material, and the mixed liquid is applied on the substrate and dried. The nonionic surfactant and the like are removed by heating the substrate in an air atmosphere at 200° C. or higher. As a result of these procedures, a bolometer thin layer 1 is formed on the substrate. Thereafter, a first and a second electrodes are produced over the bolometer thin layer at an interval of 50 μm by vapor deposition or application. An acrylic resin (PMMA) solution is applied to the region between the electrodes on the bolometer thin layer formed to form a protective layer of PMMA. Thereafter, the entire substrate is subjected to oxygen plasma treatment to remove the excess carbon nanotubes and the like on the region other than bolometer thin film layer. Excess solvents, impurities, and the like are removed by heating in an air atmosphere at 200° C.

As used herein, the term “bolometer thin film” or “bolometer film” is a thin film constituted by a plurality of carbon nanotubes forming conductive paths which electrically connect the first electrode and the second electrode, and a negative thermal expansion material. The plurality of carbon nanotubes may form a structure such as, for example, parallel, fibrous, and network, and preferably form a three-dimensional network structure in which aggregation is less likely to occur and uniform conductive paths can be obtained. As used herein, the term “bolometer material” may refers to a “bolometer thin film.”

As the carbon nanotubes, single-walled, double-walled, and multi-walled carbon nanotubes may be used, but when semiconducting carbon nanotubes are separated, single-walled or few-walled (for example, double-walled or triple-walled) carbon nanotubes are preferred, and single-walled carbon nanotubes are more preferred. The carbon nanotubes preferably comprise single-walled carbon nanotubes in an amount of 80% by mass or more, and more preferably 90% by mass or more (including 100% by mass).

The diameter of the carbon nanotubes is preferably between 0.6 and 1.5 nm, more preferably 0.6 nm to 1.2 nm, and further preferably 0.7 to 1.1 nm, from the viewpoint of increasing the band gap to improve TCR. In one embodiment, the diameter of 1 nm or less may be particularly preferred in some cases. When the diameter is 0.6 nm or more, the manufacture of carbon nanotubes becomes much easier. When the diameter is 1.5 nm or less, the band gap is easily maintained in an appropriate range and a high TCR can be obtained.

As used herein, the diameter of the carbon nanotubes means that when the carbon nanotubes on a substrate (or on any predetermined base material such as the heat insulating layer described later) or of a formed thin film are observed using an atomic force microscope (AFM) and the diameter thereof is measured at about 100 positions, 60% or more, preferably 70% or more, optionally preferably 80% or more, more preferably 100% thereof is within a range of 0.6 to 1.5 nm. It is preferred that 60% or more, preferably 70% or more, optionally preferably 80% or more, and more preferably 100% thereof be within a range of 0.6 to 1.2 nm, and further preferably within a range of 0.7 to 1.1 nm. In one embodiment, 60% or more, preferably 70% or more, optionally preferably 80% or more, and more preferably 100% thereof is within a range of 0.6 to 1 nm.

Radial breathing mode (RBM) of Raman spectra can also be used to evaluate the diameter of single-walled carbon nanotubes.

The length of the carbon nanotubes is preferably between 100 nm to 5 μm because dispersion is easy and application properties are excellent. Also, from the viewpoint of conductivity of the carbon nanotubes, the length is preferably 100 nm or more. When the length is 5 μm or less, aggregation on a substrate or on a predetermined base material, and/or upon forming a film is easily suppressed. The length of the carbon nanotubes is more preferably 500 nm to 3 μm, and further preferably 700 nm to 1.5 μm.

As used herein, the length of the carbon nanotubes means that, when at least 100 carbon nanotubes are observed using an atomic force microscope (AFM) and enumerated to measure the distribution of the length of the carbon nanotubes, 60% or more, preferably 70% or more, optionally preferably 80% or more, and more preferably 100% thereof is within a range of 100 nm to 5 μm. It is preferred that 60% or more, preferably 70% or more, optionally preferably 80% or more, and more preferably 100% thereof be within a range of 500 nm to 3 μm. It is more preferred that 60% or more, preferably 70% or more, optionally preferably 80% or more, and more preferably 100% thereof be within a range of 700 nm to 1.5 μm.

When the diameter and length of the carbon nanotubes are within the above range, the influence of semiconductive properties becomes large and a large current value can also be obtained, and thus, a high TCR value is likely to be obtained when the carbon nanotubes are used in an infrared sensor.

For the bolometer film, semiconducting carbon nanotubes having a large band gap and carrier mobility are preferably used. The content of the semiconducting carbon nanotubes, preferably single-walled semiconducting carbon nanotubes in carbon nanotubes is generally 67% by mass or more, more preferably 70% by mass or more, particularly preferably 80% by mass or more, and in particular, preferably 90% by mass or more, more preferably 95% by mass or more, and further preferably 99% by mass or more (the upper limit may be 100% by mass). In the present specification, the ratio (mass %) of semiconducting carbon nanotubes in carbon nanotubes may also be referred to as “semiconductor purity.”

In the present specification, the negative thermal expansion material means a material that has a negative coefficient of expansion and contracts as the temperature rises. Examples of the negative thermal expansion material include a material having a coefficient of linear thermal expansion ΔL/L ((length after expansion−length before expansion)/length before expansion) per temperature difference of 1K preferably ranging from −1×10⁻⁶/K to −1×10⁻³/K, more preferably from −1×10⁻⁵/K to −1×10⁻³/K, in any temperature range from −100 to +200° C., for example, the range from −100 to +100° C., preferably in the temperature range over which the infrared sensor is used, for example, at least in the range from −50 to 100° C.

The coefficient of thermal expansion can be measured in accordance, for example, with JIS Z 2285 (method for measuring coefficient of linear expansion of metallic materials) or JIS R 1618 (method for measuring thermal expansion of fine ceramics based on thermo-mechanical analysis).

In an embodiment, the negative thermal expansion material is preferably a material that exhibits sufficient negative thermal expansion in the environment in which the infrared sensor is used. The temperatures of the environment in which the infrared sensor is used range, for example, from −350° C. to 100° C., preferably from −40° C. to 80° C., more preferably in some cases from 20° C. to 30° C., for example, from 21° C. to 30° C.

The humidity in the environment in which the infrared sensor is used, for example, in a case where the bolometer part of the infrared sensor is used in a structure in which the bolometer part is exposed to the atmosphere, may be the ambient humidity, preferably, for example, 75% RH or lower. When the bolometer is vacuum-packaged or used in a structure in which the package is filled with an inert gas, the humidity is preferably, for example, 5% RH or lower, and may not fall within the range described above depending on the degree of vacuum and other factors. From the viewpoint of long-term stability of the device, lower humidity is preferable, so that the lower limit is not limited to a specific value in either case, and the humidity is 0% RH or higher, for example, higher than 0% RH.

The resistivity of the negative thermal expansion material described above is not limited to a specific value, and can range from 10⁻¹ Ωcm to 10⁸ Ωcm, preferably from 10 Ωcm to 10⁸ Ωcm, more preferably 10² Ωcm to 10⁷ Ωcm, further more preferably 10⁶ Ωcm or less in any temperature range from −100 to +100° C., preferably at the temperature at which the infrared sensor is used, for example, at room temperature (about 23° C.). The resistivity can be measured in accordance with standard methods, for example, JIS K 7194 and JIS K 6911.

In the present specification, the negative thermal expansion material may include oxides, nitrides, sulphides or multi-element compounds containing one or two or more of Li, Al, Fe, Ni, Co, Mn, Bi, La, Cu, Sn, Zn, V, Zr, Pb, Sm, Y, W, Si, P, Ru, Ti, Ge, Ca, Ga, Cr, Cd, but not limited thereto. A mixture of two or more compounds may be used.

The negative thermal expansion material may include, but not limited thereto, vanadium oxides, β-eucryptite, bismuth-nickel oxides, zirconium tungstate, ruthenium oxides, manganese nitrides, lead titanate, samarium monosulphide and others (including those in which one or more of the elements of these compounds have been replaced by the above elements). For example, LiAlSiO₄, ZrW₂O₈, Zr₂WO₄(PO₄)₂, BiNi₁₋ₓFeₓO₃ (0.05≤x≤0.5), such as BiNi_{0.85}Fe_{0.15}O₃, Bi_{1.95}La_{0.05}NiO₃, Pb_{0.76}La_{0.04}Bi_{0.20}VO₃, Sm_{0.78}Y_{0.22}S, Cu_{1.8}Zn_{0.2}V₂O₇, Cu₂V₂O₇, 0.4PbTiO₃-0.6BiFeO₃, MnCo_{0.98}Cr_{0.02}Ge, Ca₂RuO_{3.74}, Mn₃Ga_{0.7}Ge_{0.3}N_{0.88}C_{0.12}, Cd(CN)_{2-X}CCl₄, LaFe_{10.5}Co_{1.0}Si_{1.5}, Ca₂RuO₄, MnₓSn_{y}Zn_{z}N (3≤x≤4, 0.1≤y≤0.5, 0.1≤z≤0.8), such as Mn_{3.27}Zn_{0.45}Sn_{0.28}N, Mn₃Ga_{0.9}Sn_{0.1}N_{0.9}, Mn₃ZnN are suitable.

In one embodiment, among the negative thermal expansion materials, oxides, nitrides, and sulphides are preferable from the view point of ease of synthesis and availability.

In particular, when an oxide is used as the negative thermal expansion material, it has good binding property with the surface functional groups of the carbon nanotubes (—COOH, —OH, etc.), which also has the advantage of suppressing structural degradation caused by temperature cycling, reducing hysteresis upon temperature increase and decrease of the bolometer thin film, and improving durability.

In an embodiment, a material with high stability during the manufacturing processes is preferred, such as an oxide with low solubility in water or the like.

In the present specification, the size of the negative thermal expansion material can be selected as appropriate. Preferably, it is between 10 nm and 100 μm, more preferably 15 nm to 10 μm, and in some cases, it is also preferred to be between 50 nm and 5 μm, and it is particularly preferred to be 1 μm or less.

The form of the negative thermal expansion material is not particularly limited, but may be, for example, spherical, needle, rod, plate, fibre, scale and the like, with spherical being preferred in terms of film formability.

As used herein, the thickness of the bolometer thin film is not particularly limited, but in the range of, for example, 1 nm or more, for example a few nm to 100 nm, preferably 10 nm to 10 μm, more preferably 50 nm to 1 μm. In an embodiment, it is preferably 20 nm to 500 nm, more preferably 50 nm to 200 nm.

When the thickness of the bolometer film is 1 nm or more, a good infrared absorption rate can be achieved.

When the thickness of the bolometer film is 10 nm or more, preferably 50 nm or more, the element structure can be made simpler because an adequate infrared absorption rate is obtained even without comprising a light reflection layer (infrared reflection layer) or a light absorbing structure/infrared absorbing layer (light absorbing layer).

In addition, from the view point of simplifying the manufacturing method, it is preferred that the thickness of the bolometer film is 1 μm or less, preferably 500 nm or less. Also, when the bolometer film is too thick, the contact electrode deposited from above may not fully contact the carbon nanotubes at the bottom side of the bolometer film, and the effective resistance value becomes higher, but when the thickness is within the above range, increase of the resistance value can be suppressed.

Also, in the case of comprising an infrared absorbing layer, it is also possible to make the bolometer film thinner than the above range in order to further simplify the manufacturing process and improve the resistance value.

Also, when the thickness of the bolometer film is in the range of 10 nm to 1 μm as described above, it is also preferable in that printing techniques can be suitably applied to the manufacturing method of the bolometer film.

The thickness of the bolometer film can be determined as an average value of the thickness of the carbon nanotube film measured at arbitrary 10 positions.

The density of the bolometer film is, for example, 0.3 g/cm³ or more, preferably 0.8 g/cm³ or more, more preferably 1.1 g/cm³ or more. The upper limit thereof is not particularly limited, but can be the upper limit of the true density of the carbon nanotube used (for example, about 1.4 g/cm³).

When the density of the bolometer film is 0.3 g/cm³ or more, a good infrared absorbing rate can be achieved.

When the density of the bolometer film is 0.5 g/cm³ or more, it is preferred in that the element structure can be simplified because an adequate infrared absorption rate is obtained even without comprising a light reflection layer or an infrared absorbing layer.

Also, when an infrared absorbing layer is comprised, the density of the bolometer film of lower than the above-described density may be appropriately employed.

The density of the bolometer film can be calculated from weight, area, and the thickness obtained as above of the carbon nanotube film.

In addition to the above-mentioned components described above, ionic conductors (surfactants, ammonium salts, inorganic salts), resins, organic binders, and the like may also be appropriately used in the bolometer thin film.

In the infrared sensor of the present embodiment, the distance between its electrodes is preferably 1 μm to 500 μm, and for miniaturization, it is more preferably 5 to 200 μm. When the distance is 5 μm or more, for example, a reduction in the nature of TCR can be suppressed, even in the case of containing a small amount of metallic carbon nanotubes. In addition, the distance of 500 μm or less is advantageous when the infrared sensor is applied to an image sensor by two-dimensionally arraying the infrared sensors. The electrodes may by formed on the upper side of the bolometer film, or may be formed below the bolometer film.

The content of carbon nanotubes in the bolometer thin film connecting the first electrode and the second electrode can be selected appropriately, and preferably more than 0.1% by mass or more based on the total mass of the thin film is effective, more preferably 1% by mass or more is effective, for example 30% by mass, and even 50% by mass or more may also be preferred, and in some cases 60% by mass or more may be preferred.

The amount of negative thermal expansion material in the bolometer thin film (i.e., the thin film comprising semiconducting carbon nanotubes and a negative thermal expansion material) can be selected as appropriate, but it is preferable that it is contained in the semiconducting carbon nanotubes in an amount of 1 to 99% by mass based on the total mass of the thin film, with 1 to 70% by mass being more preferable, for example, 1 to 50% by mass, in some cases 10 to 50% by mass, and optionally 40% by mass or less may also be preferred.

In addition to the carbon nanotubes and the negative thermal expansion material, the bolometer thin film may also comprise a binder described later and, if desired, other components, but it is preferred that the total mass of the carbon nanotubes and the negative thermal expansion material is 70% by mass or more, more preferably 90% by mass or more, and even more preferably 95% by mass or more, based on the mass of the bolometer thin film.

As the constitutions of the substrate, electrode, and the like, those mentioned below may be used.

The infrared sensor with the bolometer thin film comprising carbon nanotubes and a negative thermal expansion material as mentioned above may be manufactured by, for example, a method comprising a cutting and dispersion step and a separation step of carbon nanotubes comprising a nonionic surfactant as described below, and a mixing step of the separated carbon nanotubes and the negative thermal expansion material, but may also be manufactured using other methods.

An example of the method for manufacturing a bolometer thin film and an infrared sensor according to one embodiment of the present invention will be described in detail below.

From the carbon nanotubes, surface functional groups and impurities such as amorphous carbon, catalysts, and the like may be removed by performing a heat treatment under an inert atmosphere, in a vacuum. The heat treatment temperature may be appropriately selected and is preferably 800 to 2000° C., and more preferably 800 to 1200° C.

The nonionic surfactant may be appropriately selected, and it is preferred to use nonionic surfactants constituted by a hydrophilic portion which is not ionized and a hydrophobic portion such as an alkyl chain, for example, nonionic surfactants having a polyethylene glycol structure exemplified by polyoxyethylene alkyl ethers, and alkyl glucoside based nonionic surfactants, singly or in combination. As such a nonionic surfactant, polyoxyethylene alkyl ether represented by Formula (1) is preferably used. In addition, the alkyl moiety may have one or a plurality of unsaturated bonds.

CₙH₂ₙ₊₁(OCH₂CH₂)ₘOH (1)

wherein, n=preferably 12 to 18, and m=10 to 100, and preferably 20 to 100.

In particular, a nonionic surfactant specified by polyoxyethylene (n) alkyl ether (wherein n=20 or more and 100 or less, and the alkyl chain length is C12 or more and C18 or less) such as polyoxyethylene (23) lauryl ether, polyoxyethylene (20) cetyl ether, polyoxyethylene (20) stearyl ether, polyoxyethylene (10) oleyl ether, polyoxyethylene (10) cetyl ether, polyoxyethylene (10) stearyl ether, polyoxyethylene (20) oleyl ether, polyoxyethylene (100) stearyl ether is more preferred. In addition, N,N-bis[3-(D-gluconamido)propyl]deoxycholamide, n-dodecyl β-D-maltoside, octyl β-D-glucopyranoside, and digitonin may also be used.

As the nonionic surfactant, polyoxyethylene sorbitan monostearate (molecular formula: C₆₄H₁₂₆O₂₆, trade name: Tween 60, manufactured by Sigma-Aldrich, etc.), polyoxyethylene sorbitan trioleate (molecular formula: C₂₄H₄₄O₆, trade name: Tween 85, manufactured by Sigma-Aldrich, etc.), octylphenol ethoxylate (molecular formula: C₁₄H₂₂O(C₂H₄O)ₙ, n=1 to 10, trade name: Triton X-100, manufactured by Sigma-Aldrich, etc.), polyoxyethylene (40) isooctylphenyl ether (molecular formula: C₈H₁₇C₆H₄O(CH₂CH₂O)₄₀H, trade name: Triton X-405, manufactured by Sigma-Aldrich, etc.), poloxamer (molecular formula: C₅H₁₀O₂, trade name: Pluronic, manufactured by Sigma-Aldrich, etc.), polyvinyl pyrrolidone (molecular formula: (C₆H₉NO)ₙ, n=5 to 100, manufactured by Sigma-Aldrich, etc.) and the like may be used.

The method for obtaining a dispersion solution of carbon nanotubes is not particularly limited, and conventionally known methods can be applied. For example, a carbon nanotube mixture, a dispersion medium, and a nonionic surfactant are mixed to prepare a solution containing carbon nanotubes, and this solution is subjected to sonication to disperse the carbon nanotubes, thereby preparing a carbon nanotube dispersion liquid (micelle dispersion solution). The dispersion medium is not particularly limited, as long as it is a solvent that allows carbon nanotubes to disperse and suspend during the separation step, and for example, water, heavy water, an organic solvent, an ionic liquid, or a mixture thereof may be used, and water and heavy water are preferred. In addition to or instead of the sonication mentioned above, a technique of dispersing carbon nanotubes by a mechanical shear force may be used. The mechanical shearing may be performed in a gas phase. In a micelle dispersion aqueous solution of the carbon nanotubes and the nonionic surfactant, the carbon nanotubes are preferably in an isolated state. Thus, if necessary, bundles, amorphous carbon, impurity catalysts, and the like may be removed using an ultracentrifugation treatment. During the dispersion treatment, the carbon nanotubes can be cut, and the length thereof can be controlled by changing the grinding conditions of the carbon nanotubes, ultrasonic output, ultrasonic treatment time, and the like. For example, the aggregate size can be controlled by grinding the untreated carbon nanotubes using tweezers, a ball mill, or the like. After these treatments, the length can be controlled to 100 nm to 5 μm using an ultrasonic homogenizer by setting the output to 40 to 600 W, optionally 100 to 550 W, 20 to 100 KHz, the treatment time to 1 to 5 hours, preferably up to 3 hours. When the treatment time is shorter than 1 hour, the carbon nanotubes may be hardly dispersible depending on the conditions, and may remain almost the original length in some cases. From the viewpoint of shortening the dispersion treatment time and reducing the cost, the treatment time is preferably 3 hours or less. The present embodiment may also have the advantage of ease of adjustment of cutting due to use of a nonionic surfactant. In addition, the infrared sensor according to the present embodiment manufactured using the carbon nanotubes prepared by a method using a nonionic surfactant has the advantage of containing no ionic surfactant which is difficult to be removed.

Dispersion and cutting of the carbon nanotubes generate a surface functional group at the surface or the end of the carbon nanotube. Functional groups such as carboxyl group, carbonyl group, and hydroxyl group are generated. When the treatment is performed in a liquid phase, a carboxyl group and a hydroxyl group are generated, and when the treatment is performed in a gas phase, a carbonyl group is generated.

When these surface functional groups are present and an oxide is used as the negative thermal expansion material, structural deterioration of the infrared sensor due to temperature cycle can be suppressed in some cases as these functional groups have good binding properties to the oxide, and can enhance the binding between carbon nanotubes via a compound having an amino group, and can also express an anchor effect to the substrate.

The concentration of the surfactant in the liquid comprising heavy water or water and a nonionic surfactant mentioned above is preferably from the critical micelle concentration to 10% by mass, and more preferably from the critical micelle concentration to 3% by mass. The concentration of the critical micelle concentration or less is not preferred because dispersion is impossible. When the concentration is 10% by mass or less, a sufficient density of carbon nanotubes can be applied after separation, while reducing the amount of surfactant. As used herein, the critical micelle concentration (CMC) refers to the concentration serving as an inflection point of the surface tension measured by, for example, changing the concentration of an aqueous surfactant solution using a surface tensiometer such as a Wilhelmy surface tensiometer at a constant temperature. As used herein, the “critical micelle concentration” is a value under atmospheric pressure at 25° C.

The concentration of the carbon nanotubes in the above cutting and dispersion step (the weight of the carbon nanotubes/(the total weight with the dispersion medium and the surfactant)×100) is not particularly limited, and for example, may be 0.0003 to 10% by mass, preferably 0.001 to 3% by mass, and more preferably 0.003 to 0.3% by mass.

The dispersion liquid obtained through the aforementioned cutting and dispersion step may be used as it is in the separation step mentioned below, or steps such as concentration and dilution may be performed before the separation step.

Separation of the carbon nanotubes can be performed by, for example, the electric-field-induced layer formation method (ELF method: see, for example, K. Ihara et al. J. Phys. Chem. C. 2011, 115, 22827 to 22832 and Japanese Patent No. 5717233, which are incorporated herein by reference). One example of the separation method using the ELF method will be described. Carbon nanotubes, preferably single-walled carbon nanotubes are dispersed by a nonionic surfactant, and the dispersion liquid is put into a vertical separation apparatus, and then a voltage is applied to the electrodes arranged above and below, so that the carbon nanotubes are separated by free flow electrophoresis. The mechanism of separation can be inferred as follows for example. When the carbon nanotubes are dispersed by the nonionic surfactant, the micelle of the semiconducting carbon nanotubes has a negative zeta potential, whereas the micelle of the metallic carbon nanotubes has an opposite (positive) zeta potential (in recent years, it is considered that the metallic carbon nanotubes have a slightly negative zeta potential or are barely charged). Thus, when an electric field is applied to the carbon nanotube dispersion liquid, the micelle of the semiconducting carbon nanotubes is electrophoresed toward the anode (+) direction, and the micelle of the metallic carbon nanotubes is electrophoresed toward the cathode (−) direction by the difference between the zeta potentials, and the like. Eventually, the layer in which the semiconducting carbon nanotubes are concentrated is formed near the anode, and the layer in which the metallic carbon nanotubes are concentrated is formed near the cathode in the separation tank. The voltage for separation may be appropriately set in consideration of the composition of the dispersion medium, the charge amount of carbon nanotubes, and the like, and is preferably 1 V or more and 200 V or less, and more preferably 10 V or more and 200 V or less. It is preferably 100 V or more from the viewpoint of shortening the time for the separation step. It is preferably 200 V or less from the viewpoint of suppressing the generation of bubbles during separation and maintaining the separation efficiency. The purity is improved by repeating separation. The same separation procedure may be performed by resetting the dispersion liquid after separation to the initial concentration. As a result, the purity can be further increased.

Through the aforementioned dispersion and cutting step and separation step of the carbon nanotubes, a dispersion liquid in which the semiconducting carbon nanotubes having the desired diameter and length are concentrated can be obtained. As used herein, the carbon nanotube dispersion liquid in which semiconducting carbon nanotubes are concentrated may be referred to as the “semiconducting carbon nanotube dispersion liquid”. The semiconducting carbon nanotube dispersion liquid obtained by the separation step comprises semiconducting carbon nanotubes generally 67% by mass or more, preferably 70% by mass or more, more preferably 80% by mass or more in the total amount of carbon nanotubes, and it is particularly preferably 90% by mass or more, more preferably 95% by mass or more, further preferably 99% by mass or more (the upper limit may be 100% by mass). The separation tendency of the metallic and semiconducting carbon nanotubes can be analyzed by microscopic Raman spectroscopy and ultraviolet-visible near-infrared absorptiometry.

The centrifugation treatment may be performed to remove the bundles, amorphous carbon, metal impurities, and the like in the carbon nanotube dispersion liquid after the aforementioned dispersion and cutting step of the carbon nanotubes and before the separation step. The centrifugal acceleration may be appropriately adjusted, and is preferably 10000×g to 500000×g, more preferably 50000×g to 300000×g, and optionally 100000×g to 300000×g. The centrifugation time is preferably 0.5 hours to 12 hours, and more preferably 1 to 3 hours. The centrifugation temperature may be appropriately adjusted, and is preferably 4° C. to room temperature, and more preferably 10° C. to room temperature.

The concentration of the surfactant in the carbon nanotube dispersion liquid after separation may be appropriately controlled. The concentration of the surfactant in the carbon nanotube dispersion liquid is preferably from the critical micelle concentration to about 5% by mass, more preferably, 0.001% by mass to 3% by mass, and particularly preferably 0.01 to 1% by mass to suppress the reaggregation after application and the like.

A mixed dispersion liquid comprising semiconducting carbon nanotubes and a negative thermal expansion material (semiconducting carbon nanotubes/negative thermal expansion material dispersion liquid) can be obtained by mixing a negative thermal expansion material into the semiconducting carbon nanotube dispersion liquid comprising obtained by the above steps.

The mixing ratio of the semiconducting carbon nanotubes and the negative thermal expansion material in the dispersion liquid can be selected as appropriate, but the semiconducting carbon nanotubes is preferably 0.01% by mass to 99% by mass, more preferably 0.1% by mass to 90% by mass, for example, 30% by mass or more, and furthermore, 50% by mass to 85% by mass is also preferred, based on the total mass of the semiconducting carbon nanotubes and the negative thermal expansion material.

When mixing the negative thermal expansion material into the semiconducting carbon nanotube dispersion liquid obtained by the above steps, a binder or the like may also be added. By adding a binder, the viscosity can be more easily adjusted, and the dispersion liquid can be more easily applied. It also prevents the semiconducting carbon nanotubes and thermal expansion material from agglomerating or settling after application, making it easier to produce a more uniform coating film. The type of the binder can be appropriately selected, examples of which include polyvinylidene fluoride, acrylic resin, styrene butadiene rubber, imide resin, imideamide resin, polytetrafluoroethylene resin, polyamic acid, vinylidene fluoride-hexafluoropropylene, vinylidene fluoride-tetrafluoroethylene, polypropylene, polyethylene, polyimide, polyamideimide, methyl(meth)acrylate, ethyl(meth)acrylate, butyl(meth)acrylate, (meth)acrylonitrile, isoprene rubber, butadiene rubber, and fluoro rubber. Mixtures of two or more binders may be used. When a binder is used, the content is not particularly limited, but, for example, more than 0% by mass, preferably 0.01% by mass or more, for example, 0.1% by mass or more, and 30% by mass or less, preferably 10% by mass or less, preferably 5% by mass or less based on the total mass of semiconducting carbon nanotubes and negative thermal expansion material.

The semiconducting carbon nanotube/negative thermal expansion material dispersion liquid obtained by the processes described above can be applied on the substrate or on a predetermined base material, dried, and, optionally heat treated to form a bolometer thin film.

The substrate may be either a flexible substrate or a rigid substrate, and may be appropriately selected, and those in which at least the element forming surface has insulating property or semiconducting property are preferred. For examples, Si, SiO₂-coated Si, SiO₂, SiN, parylene, polymers, resins, plastics, and the like, but is not limited thereto.

The method for applying the semiconducting carbon nanotube/negative thermal expansion material dispersion liquid to the substrate or a predetermined base material is not particularly limited, and examples thereof include dropping method, spin coating, printing, inkjet, spray coating, dip coating, and the like. From the viewpoint of reducing the manufacturing cost of infrared sensor, a printing method is preferred. The printing methods can include application (dispenser, inkjet or the like), transferring (microcontact print, gravure printing, or the like) and the like.

The semiconducting carbon nanotubes/negative thermal expansion material dispersion liquid applied on the substrate or a predetermined based material may be subjected to a heat treatment to remove the surfactant and the solvent. The temperature of the heat treatment may be appropriately set as long as it is equal to or higher than the decomposition temperature of the surfactant, and it is preferably 150 to 500° C., and more preferably 200 to 500° C., for example 200 to 400° C. A temperature of 200° C. or more is preferred because the remaining of the decomposition product of the surfactant can be easily suppressed. A temperature of 500° C. or less, for example 400° C. or less is preferred because the change in the quality of the substrate or other components can be suppressed. Also, the decomposition of carbon nanotubes, the change in size, the leaving of functional groups, and the like can be suppressed.

The first electrode and the second electrode on the substrate can be produced using, for example, gold, platinum, and titanium singly or in combination. The method for producing the electrode is not particularly limited, and examples thereof include vapor deposition, sputtering, and printing method. The thickness may be appropriately adjusted and is preferably 10 nm to 1 mm, and more preferably 50 nm to 1 μm. The above dispersion liquid may be applied to the substrate on which the electrodes are provided in advance, or the electrode may be produced after the dispersion liquid is applied, before or after the heat treatment.

A protective film may be provided on the surface of the bolometer thin film, if necessary. The protective film is preferably a material with high transparency in the infrared wavelength range to be detected. Examples thereof include acrylic resins such as PMMA and PMMA anisole, epoxy resins, and Teflon®.

The infrared sensor according to the present embodiment may be a single element or may be an array in which a plurality of elements are two-dimensionally arranged such as those used in an image sensor.

As for the structure of the element and array of the infrared sensor, the structure used for infrared sensors can be adopted without any particular restriction. Examples of suitable elements and array structures are described below, but are not limited to these.

### [1] Element Structure of Printed Type

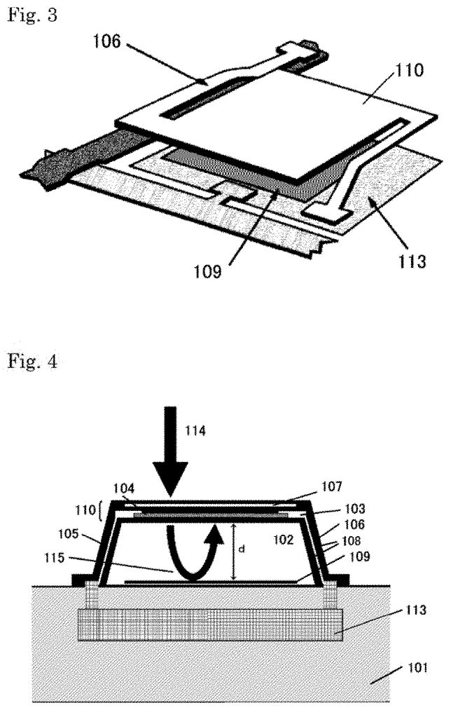

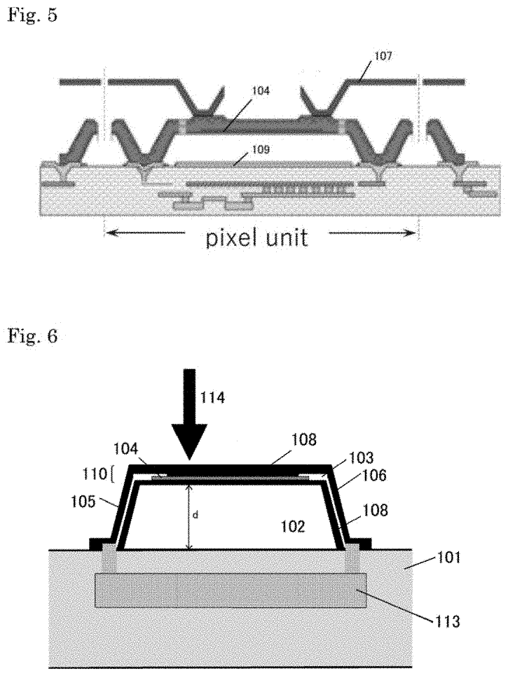

An example of a cell structure of the bolometer will be explained with reference to the figures. FIG. 3 is an oblique view, and FIGS. 4 and 5 are a vertical cross-sectional view of the element of the bolometer. This structure has a light detection unit (an infrared detection unit, a light receiving unit) 110 on a substrate (such as a silicon substrate) 101 in which a readout circuit 113 is formed, wherein the light detection unit is separated from the substrate 101 by a gap 102 with a supporting leg 106 as a support. When irradiated with an infrared ray 114, the bolometer film 104 of the infrared detection unit 110 is heated and detects the resistance change caused by temperature change. In order to improve the infrared absorption rate, an infrared reflection layer 109 may be provided to reflect the infrared light 115 that is not absorbed by and transmitted through the bolometer film 104 and make the light incident into the bolometer film again. In some cases, a light absorbing layer 107 is additionally provided directly above the bolometer film as shown in FIG. 4, or an infrared absorbing structure 107, which is called “eave”, is further provided to efficiently absorb the infrared ray incident into the pixel as shown in FIG. 5.

The bolometer thin film comprising semiconducting carbon nanotubes and a negative thermal expansion material according to the present embodiment described above has a higher infrared absorption rate than the conventional bolometer film. Therefore, one or both of the light reflection layer and the infrared absorbing layer are not necessary to be provided, and one or both of these may be omitted as shown in FIG. 6. This makes it possible to more simplify the element structure and lowering the cost of the manufacturing process.

When a light reflection layer 109 is comprised as shown in FIG. 4, it is preferable to set the distance d between the light reflection layer 109 and the bolometer film 104, namely, the height of the gap 102, to d=λ/4, taking into account the wavelength λ of the infrared rays to be absorbed. On the other hand, when the light reflection layer is omitted as shown in FIG. 6, the height of the gap d can be set freely to any desirable value, without taking into account the wavelength λ of the infrared rays to be absorbed. In this case, there is also the advantage that the infrared sensor can be used to detect electromagnetic waves in a wider wavelength range.

### [1-1] Components Constituting the Bolometer Element

Hereinafter, elements constituting the bolometer element according to the present embodiment will be each described in detail.

### (1) Bolometer Film

A bolometer thin film comprising the above-described semiconducting carbon nanotubes and a negative thermal expansion can be used as the bolometer film.

### (2) Gap

In the bolometer of the present embodiment, a gap 102 is provided between the infrared detection unit (light detection unit) 110 comprising the above-described bolometer film 104 and the substrate 101. In a bolometer equipped with a light reflecting layer 109 as shown in FIGS. 4 and 5, the height d of the gap can be preferably determined in consideration of the wavelength of infrared rays to be absorbed. In the bolometer comprising no light reflecting layer as shown in FIG. 6, the gap height d may be set to a desired value without considering the wavelength of the infrared ray to absorb. From the viewpoint of ease of fabrication, it is preferable to set the gap height d to 0.5 μm or more. The gap height d represents the distance from the top surface of the substrate 101 (or the top surface of the insulating protective film etc., if any, on the substrate) to the bottom surface of the infrared detection unit 110.

The insulation between the infrared detection unit and the substrate can also be improved by vacuum packaging the entire infrared element and keeping the gap 102 in vacuum.

### (3) Other Components

In the bolometer of the present embodiment, as a component other than the above-described bolometer film 104 and the gap 102, those used in bolometers can be used without limitation, and an example thereof will be described below. As the substrate and the electrodes, those described above can be used for example.

### (Infrared Absorbing Structure)

The bolometer of the present embodiment may comprise an infrared absorbing structure.

For example, an infrared absorbing structure 107 in a form of eave can be provided in order to efficiently absorb the incident infrared rays and further increase the fill factor as shown in FIG. 5. An example of such a structure includes those consisting of SiN, but is not limited thereto, and any structure used in the art can be used without a particular limitation.

Also, as shown in FIG. 4, an infrared absorbing layer 107 may be provided above the bolometer film 104, namely, on the side from which infrared rays are incident. The infrared absorbing layer can be provided directly on the bolometer film 104, or can be provided on a protection layer described later.

The thickness of the infrared absorbing layer depends on its material, and for example, may be from 50 nm to 1 μm.

In a case where an infrared absorbing layer 107 is provided directly on the bolometer film 104, the example thereof includes, but not limited thereto, a coating film of polyimide and the like. An example of the infrared absorbing layer 107 to be provided on a protection layer includes, but not limited thereto, a thin film of silicon nitrate and the like.

### (Protection Layer)

As shown in FIG. 4 and FIG. 6, a protection layer 108 is typically present on the bolometer film 104, and on and beneath the wiring 105. The protection layer can serve as an insulating protection layer, and when the protection layer is provided on the above side of the bolometer film, it also has effects of suppressing doping to carbon nanotubes due to the absorption of oxygen or the like, and of increasing the infrared absorption rate, which is because not only the bolometer film but also the protection layer absorbs infrared ray. Materials that are used as a protection layer in a bolometer can be used for the protection layer 108 without limitation, and examples thereof include a film of silicon nitride, and the like.

### (Light Reflection Layer)

As shown in FIG. 4 and FIG. 5, a light reflection layer 109 may be provided between the bolometer film 104 and the substrate 101, for example, on the substrate 101. The light reflection layer may also preferable to be omitted from the point of view of simplification of the element structure. As the light reflection layer 109, any material used as a light reflection layer in bolometers, examples of which include gold, silver, aluminum and the like.

### [1-2] Structure of Array

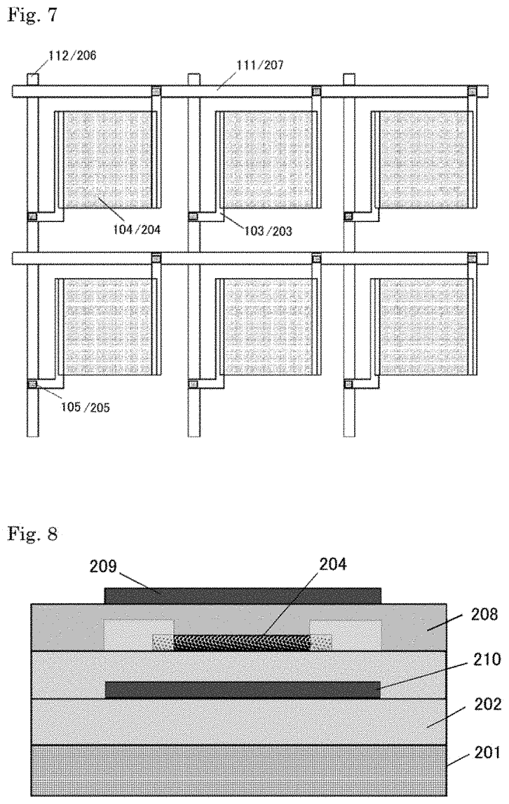

Although a bolometer of a single cell (single element) is shown in the above embodiment, a bolometer array can be made by arranging a plurality of elements in an array configuration. FIG. 7 is a plane view showing a bolometer array in which the sensor cells of FIG. 3 to FIG. 6 are arranged in an array configuration. A two-dimensional image sensor can be configured by connecting electrodes 103 of each element to a plurality of column wirings 112 for each column via contacts 105, and connecting to a plurality of row wirings 111 for each row via contacts 105. In such a structure, electrical signals are given to the row wiring 111 and the column wiring 112 corresponding to each cell, and then the resistance change of the cell is read out. An infrared image sensor is obtained by sequentially reading out the resistance changes of all cells.

### [1-3] Structure and Manufacturing Method of Bolometer and Bolometer Array

For the method for manufacturing the bolometer and bolometer array according to the present embodiment, any manufacturing process typically used for manufacturing a bolometer can be used without limitation, except that a predetermined bolometer film is used. Examples of the element structure of a bolometer array and the manufacturing method thereof will be described below.

The silicon MEMS (Micro Electro Mechanical Systems) process is usually used to fabricate elements such as those shown in FIG. 3 to FIG. 6. In the MEMS process, firstly, a readout circuit 113 is constituted with a CMOS (Complementary Metal Oxide Semiconductor) transistor and the like in a semiconductor substrate 101, and an interlayer insulating film is formed thereon by the CVD method, and a metal light reflection layer 109, an interlayer insulating film, and a sacrificial layer are formed on its upper layer. Thereafter, a protection insulating layer of silicon nitride film is formed by the CVD method, and a metal electrode 103 is formed thereon. Next, a bolometer film 104 connected to the metal electrode 103, and a second silicon nitride film 108 are formed. Finally, the sacrificial layer is removed by etching to form a gap 102 to obtain a cell of a diaphragm structure. The bolometer film 104 can be formed by a printing method as described above, and the thickness and density thereof are, for example, a thickness of 100 nm and a density of 1.1 g/cm³.

The light reflection layer may also be omitted in the above-described processes. In this case, the thickness of the sacrificial layer, namely the distance d between the light reflection layer 109 and the bolometer film 104 can be set freely without taking into account the wavelength of electromagnetic waves to be absorbed, and the manufacturing processes can be further simplified.

When an infrared absorbing layer 107 is provided in addition to the above components, it may be formed on the above bolometer film 104 or on the silicon nitrate film using a printing method or the like, or an infrared absorbing layer formed in advance may be layered.

It is also desirable to apply a transistor array to the bolometer array of the present embodiment. The application of a transistor array is advantageous in that, for example, it makes a high-speed scanning possible. The form of the transistor array is not limited, and any form used in the art can be applied without a particular limitation, for example, by building in the transistor array under the photosensitive area.

### [2] Element Structure of Printed Type

Another example of the cell structure of the bolometer is described with reference to the figures. FIG. 8 shows a vertical cross-sectional view of the element of the bolometer. In this structure, a heat insulation layer (such as parylene layer) 202 is provided on a substrate (such as polyimide substrate) 201, and a bolometer film (CNT nano-composite bolometer film) 204 is provided on the heat insulating layer 202. Electrodes are provided in contact with and on the bolometer film 204. Such a bolometer detects the intensity of infrared light by reading out the resistance change due to the temperature rise of the bolometer membrane from the electrodes.

In the bolometer of the present embodiment, the bolometer film 204 and the substrate 201 are thermally separated by the heat insulating layer 202, which prevents heat from escaping from the bolometer film 204 and improves detection sensitivity. Furthermore, the element structure is simpler than that of a bolometer of a diaphragm-type structure having a gap between the substrate 201 and the bolometer film 204, and there is also an advantage that vacuum packaging to evacuate the gap is not required.

Furthermore, since the bolometer film 204 and the heat insulating layer 202 can be fabricated using printing technology, there is also an advantage that the manufacturing cost can be lowered as compared to the case of using the MEMS process.

In the present embodiment, as shown in FIG. 8, a light reflection layer (infrared reflection layer) 201 may be provided between the bolometer film 204 and the substrate 201 in order to absorb the infrared rays that is incident from above and pass through the bolometer film without being absorbed.

Also, as shown in FIG. 8, an infrared absorbing layer 209 may be provided above the bolometer film 204, namely, on the side from which infrared rays are incident. The infrared absorbing layer can be provided on a protection layer described later, or can be provided on the bolometer film 204.

The bolometer thin film comprising semiconducting carbon nanotubes and a negative thermal expansion material according to the present embodiment described above has a higher infrared absorption rate than the conventional bolometer film. Therefore, one or both of the light reflection layer and the infrared absorbing layer are not necessary to be provided, and one or both of these may be omitted. This makes it possible to more simplify the element structure and lowering the cost of the manufacturing process.

### [2-1] Components Constituting a Bolometer Element

Hereinafter, elements constituting the bolometer element according to the present embodiment will be each described in detail.

### (1) Bolometer Film

A bolometer thin film comprising semiconducting carbon nanotubes and a negative thermal expansion described above can be used as the bolometer film.

### (2) Heat Insulating Layer

The heat insulating layer 202 is a layer interrupting the heat transmission from the carbon nanotube film 204 to the substrate 201. In the conventional bolometers, a gap is provided to serve as a structure interrupting the heat transmission from a bolometer film to a substrate, and complicated production processes are required to form such a gap. However, since the heat insulating layer in the present embodiment can be formed using a printing process and the like, and complicated production processes are thus not required. In addition, while in the conventional bolometers, the entire element is need to be vacuum packaged in order to keep the gap in vacuum, the bolometer of the present embodiment has an advantage of not requiring such vacuum packaging.

A resin component with a low heat conductivity is preferably used for the heat insulating layer. The heat conductivity of the resin component to be used for the heat insulating layer is lower than the heat conductivity of the substrate 201, and for example, is in the range of 0.02 to 0.3 (W/mK), preferably 0.05 to 0.15 (W/mK). Examples of such resin component include parylene, but not limited thereto. Parylene is a generic term for paraxylene-based polymers, and has a structure in which benzene rings are linked via CH₂. Parylene includes parylene N, parylene C, parylene D, parylene HT and the like, and among them, parylene C (heat conductivity: 0.084 (W/mK)) having the lowest heat conductivity is suitable.

The thickness of the heat insulating layer can be appropriately set in considering the heat conductivity of the component to use, and in a case of using parylene C for example, it is preferably in the range of 5 μm to 50 μm, and more preferably in the range of 10 μm to 20 μm.

When a light reflection layer is comprised to improve infrared absorption, it is preferable to set the distance d=λ/4 between the bolometer film 204 and the light reflection layer, taking into account the wavelength λ of the infrared rays to be absorbed as described above. On the other hand, when the light reflection layer is omitted, the thickness of the heat insulation layer can be set freely within the range where a desired heat insulation properties can be obtained without taking into account the wavelength λ of the infrared rays to be absorbed. In this case, there is also the advantage that the bolometer can be used to detect electromagnetic waves in a wider wavelength range.

### (3) Other Components

In the bolometer of the present embodiment, as a component other than the above-described bolometer film 204 and heat insulating layer 202, those typically used in bolometers can be used without limitation, and an example thereof will be described below. As the substrate and the electrodes, those described above can be used.

### (Infrared Absorbing Layer)

When an infrared absorbing layer 209 is provided as shown in FIG. 8, those exemplified in the MEMS type element described above can be used as the infrared absorbing layer.

### (Protection Layer)

For example, in the embodiment shown in FIG. 8, a protection layer 208 is provided on the bolometer film 204. The protection layer has effects of suppressing doping to carbon nanotubes due to the absorption of oxygen or the like, and of increasing the infrared absorption rate, which is because not only the bolometer film but also the protection layer absorbs infrared ray.

The protection layer is preferably made of a material having a high transparency in the infrared wavelength range to be detected, and examples thereof include resins used for the above-described heat insulating layer, such as parylene, and also acrylic resins such as PMMA and PMMA anisole, epoxy resins, Teflon®, silicon nitrate and the like, but not limited thereto. The thickness of the protection layer depends on its material, and may be for example 5 nm to 50 nm.

### (Light Reflection Layer)

As shown in FIG. 8, a light reflection layer 210 may be provided between the bolometer film 204 and the substrate 201, for example, between the thermal insulation layers 202. The light reflection layer is also preferable to be omitted from the point of view of simplification of the element structure. As the light reflection layer 210, those exemplified for the MEMS type element can be used.

### [2-2] Structure of Array

Furthermore, although a bolometer of a single cell (single element) is shown above, a bolometer array can be made by arranging a plurality of elements in an array configuration. FIG. 7 is a plane view showing a bolometer array in which the sensor cells of FIG. 8 are arranged in an array configuration. A two-dimensional image sensor can be configured by connecting electrodes 203 of each element to a plurality of column wirings 206 for each column via contacts 205, and to a plurality of row wirings 207 for each row via contacts 205. In such a structure, electrical signals are given to the row wiring 207 and the column wiring 206 corresponding to each cell, and then the resistance change of the cell is read out. An infrared image is obtained by sequentially reading out the resistance changes of all cells.

### [2-3] Method for Manufacturing a Bolometer

The method for manufacturing the bolometer according to the present embodiment is not particularly limited and any method used for manufacturing a bolometer can be appropriately employed. From the view point of simplifying the manufacturing processes and lowering the cost, it is preferred to form a heat insulating layer and a bolometer film on a desired substrate using a printing method or the like, but the method is not limited to the printing method.

### (1) Bolometer Film

The bolometer film can be formed by applying the semiconducting carbon nanotubes/negative thermal expansion material dispersion liquid obtained by the aforementioned processes on the aforementioned heat insulating layer, and drying the resultant. Alternatively, the semiconducting carbon nanotubes/negative thermal expansion material dispersion liquid may be applied on a desired base material to form a film, and the resulting bolometer film may be layered on the aforementioned heat insulating layer.

### (2) Heat Insulating Layer

The manufacturing method of the heat insulating layer is not particularly limited as long as the method can produce the heat insulating layer described above. For example, when a parylene film is used as the heat insulating layer, the parylene film can be formed by coating a desired area with parylene using a vacuum vapor deposition apparatus. Specifically, when solid dimer is heated under vacuum, it vaporizes to become dimer gas. This gas is thermally decomposed and the dimer is cleaved to a monomer form. In the vapor deposition chamber at room temperature, this monomer gas polymerizes on all surfaces to form a thin, transparent polymer film.

If necessary, pre-treatment of the substrate, cleaning of the substrate, and masking of the areas that should not be deposited may be performed before the vapor deposition process is performed.

### [3-3] Structure and Manufacturing Method of a Bolometer Array

An example of the structure and the manufacturing method of a bolometer array will be described with reference to the figures, but the structure and the manufacturing method of the bolometer array are not limited thereto.

### Example 1

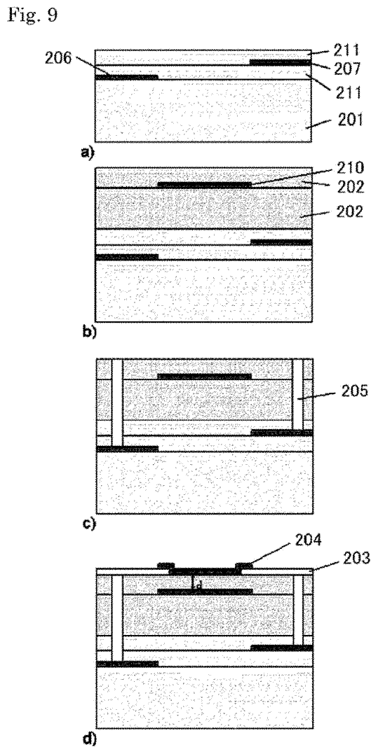

In FIG. 9(a), an aluminum film (1000 Å) is vapor-deposited on substrate 201 through a metal mask to form column wiring 206. Then, insulating film 211 is formed by applying polyimide. Row wiring 207 is formed thereon in a same manner as the column wiring. Further, second insulating film 211 is formed by applying polyimide thereon.

Next, as shown in FIG. 9(b), as heat insulating layer 202, a parylene film is formed with, for example, a thickness of about 20 μm by vapor deposition. Parylene is usually in a dimer state, and is heated to about 700° C. in a vapor deposition apparatus to becomes a monomer state, and then becomes a polymer state after being vapor-deposited on the substrate.

Then, as shown in FIG. 9(c), contact holes 205 are opened by lithography and dry etching.

Then, as shown in FIG. 9(d), electrodes 203 each connected to the row wiring and column wiring via contact holes 205 are formed. A lithography and a lift-off method can be used as the formation method. The electrode 203 may be formed by vapor deposition or printing method. The electrode 203 may also be formed after the bolometer film 204 is formed.

Thereafter, bolometer film 204 is formed. Bolometer film 204 is preferably formed by a printing method, for example, by applying the carbon nanotubes/negative thermal expansion material dispersion liquid described above by a dispenser apparatus. Here, the thickness and the density of the bolometer film are, for example, the thickness of 100 nm and the density of 1.1 g/cm³, respectively.

In the case of comprising a light reflection layer, a parylene film is formed as the heat insulation layer 202, on which a light reflection layer 210 is formed by vapor deposition of aluminum (1000 Å), on which a second heat insulation layer 202 is formed with a thickness of about 2.5 μm (distance d) by the evaporation of Parylene.

If a protective film 208 is to be provided in addition to the above components, for example, a protection layer can be formed by applying a resin solution used for the protection layer on the formed bolometer film 204. Thereafter, the entire substrate may be subjected to an oxygen plasma treatment to remove excess carbon nanotube and the like present in the areas other than the bolometer film 204.

When an infrared absorbing layer 209 is provided in addition to the above components, it may be formed on the above bolometer film 204 or on a protection film 208 using a printing method or the like, or an infrared absorbing layer formed in advance may be layered or transferred.

The following example shows an example of the method for manufacturing a bolometer that does not have a light reflection layer, an infrared absorption layer, or a protective layer. Of course, however, the manufacturing method may additionally include steps of forming a light reflection layer, an infrared absorption layer, a protective layer, and the like.

### Example 2

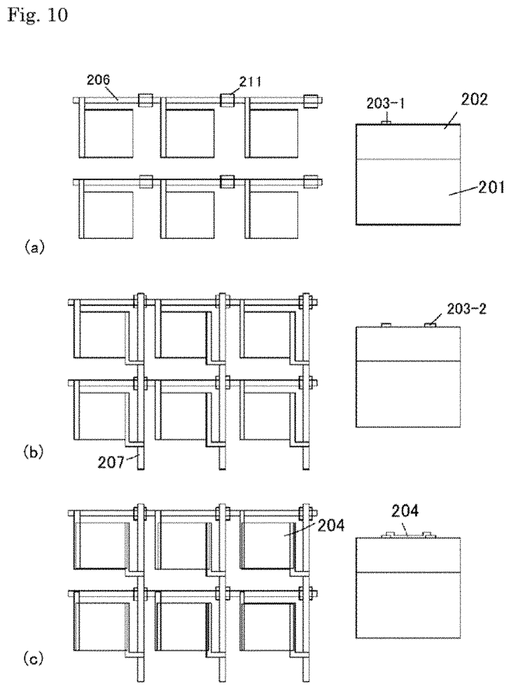

Another example will be explained with reference to FIG. 10.

First, as shown in FIG. 10(a), heat insulating layer 202 is formed on substrate 201, and first electrode 203-1 and column wiring 206 are formed thereon. The first electrode and the column wiring can be made of the same material and formed simultaneously by vapor deposition or a printing method.

Next, insulating film 211 is formed to insulate a part of row wiring 206 that intersects with a row wiring in a later process. A method of forming the insulating film includes coating polyimide to form a film using a printing method.

Next, as shown in FIG. 10(b), second electrode 203-2 and row wiring 207 are formed in a same manner as the first electrode and the column wiring.

Next, as shown in FIG. 10(c), bolometer film 204 connected with the first and second electrodes is formed.

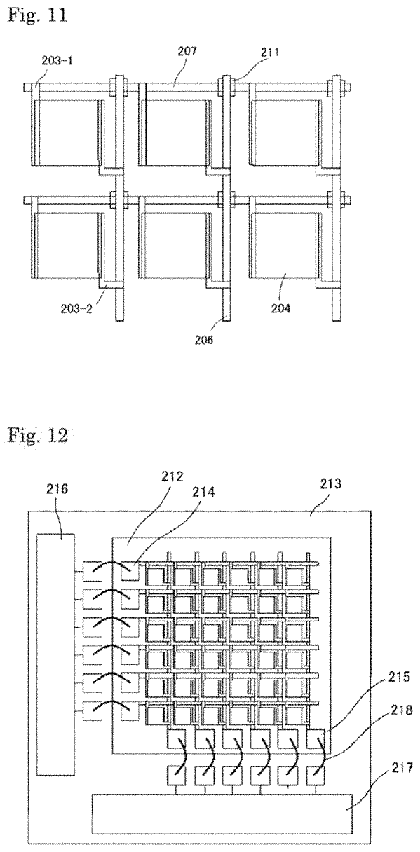

According to such a method, a bolometer array as shown in FIG. 11 can be manufactured using a printing process and the like without performing a contact formation, which enables further cost reduction.

### Example 3

Another example will be explained with reference to FIG. 12.

In the bolometer array of FIG. 12, a bolometer array is formed on first substrate 212, such as a resin substrate, and a readout circuit is formed on second substrate 213, which is a semiconductor substrate, using an ordinary silicon CMOS process (not shown). An insulating layer is formed on the readout circuit, and the first substrate is attached on the second substrate. The bolometer array of the present embodiment can be formed by electrically connecting column terminals 214 and row terminals 215 of the first substrate to the terminals leading to column selecting circuit 216 and row selecting circuit 217 in the readout circuit on the second substrate using bonding wires 218 or the like.

### Example 4

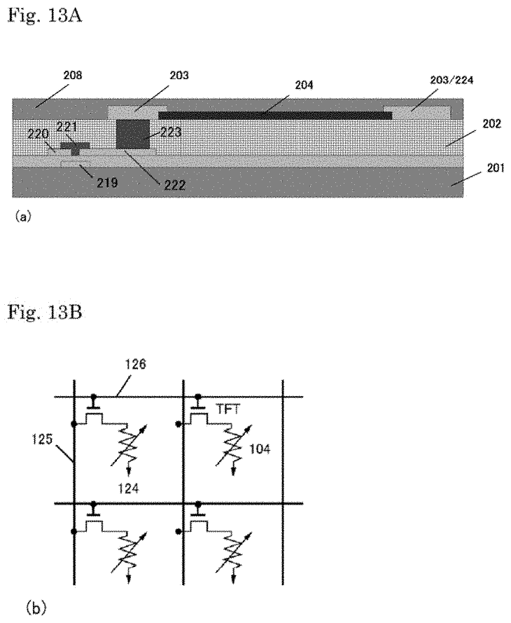

Another example will be explained with reference to FIG. 13.

A TFT (thin-film transistor) array is also preferably applied to the array sensor according to the present embodiment. The application of a TFT array makes possible high-speed scanning. The form of the TFT array is not particularly limited, and one example thereof is shown in FIG. 13. In the TFT array shown in FIG. 13A, gate electrode 219 is placed on substrate 201, and source electrode 220 and drain electrode 122 are formed on the upper layer thereof with an insulating layer therebetween. Heat insulating layer 202, bolometer film 204, and protective film 208 are formed on the upper layer thereof. Drain electrode 222 is connected to pixel electrode 203, which is formed in contact with the bolometer film 204, through via 223 that extends through heat insulating layer 202. The other electrode 203 is connected to common electrode 224. The two-dimensional arrangement of the pixel circuit of this TFT array is shown in FIG. 13B.

### EXAMPLES

The present invention will be described further in detail by way of Examples below. Of course, the present invention should not be limited by the following examples.

### Example 1

### (Step 1)

100 mg of single-walled carbon nanotubes (Meijo Nano Carbon Co., Ltd., EC 1.0 (diameter: about 1.1 to 1.5 nm (average diameter 1.2 nm)) was put in a quartz boat and inserted into an electric furnace and heat treatment was performed at 900° C. for two hours under a vacuum atmosphere. The surface functional groups and impurities were removed, and the weight after heat treatment was 80 mg. 12 mg of the obtained single-walled carbon nanotubes was immersed in 40 ml of an aqueous solution of 1 wt % surfactant (polyoxyethylene (100) stearyl ether) and ultrasonic dispersion treatment (BRANSON ADVANCED-DIGITAL SONIFIER apparatus (output: 50 W)) was performed for three hours. Through this step, aggregates of the carbon nanotubes in the solution were eliminated. The obtained solution was subjected to ultracentrifugation treatment under conditions of 50000 rpm at 10° C. for 60 minutes. Through this procedure, bundles, remaining catalysts, and the like were removed to obtain a carbon nanotube dispersion liquid.

### (Step 2)

The carbon nanotube dispersion liquid was introduced into the separation apparatus to extract semiconducting carbon nanotubes by ELF method. Their analysis by optical absorption spectra showed that the metallic carbon nanotube component was removed. The Raman spectra also showed that 99 wt % was semiconducting carbon nanotubes.

### (Step 3)

Negative thermal electrical material (negative thermal expansion material) (Cu_{1.8}Zn_{0.2}V₂O₇, thermal expansion coefficient: −14 ppm/K, resistivity: 105 Ωcm, size: 20 nm, shape: spherical) was mixed to the semiconducting carbon nanotube dispersion liquid so that the ratio by weight of the semiconducting carbon nanotubes was 70%. A dispersion liquid of semiconducting carbon nanotubes/negative thermal electrical material was prepared by ultrasonic treatment.

### (Step 4)

A substrate in which a silicon substrate is coated with 100 nm of SiO₂ was prepared. The substrate was washed, and immersed in a 0.1% APTES aqueous solution for 30 minutes. After washing, the substrate was dried at 105° C. A semiconducting carbon nanotubes/negative thermal electrical material dispersion liquid was added dropwise on the obtained substrate, and dried at 110° C. The substrate was heated in an air atmosphere at 200° C. to remove the nonionic surfactant and the like. Thereafter, gold was vapor deposited to a thickness of 50 nm at two positions on the substrate at an interval of 100 μm. Then, a PMMA anisole solution was applied between the electrodes to protect the carbon nanotubes between the electrodes, and then, excess carbon nanotubes and the like near the electrodes were removed by oxygen plasma treatment. Thereafter, the substrate was dried at 200° C. for one hour to produce an infrared sensor. The AFM observation showed that at least 70% of carbon nanotubes had a diameter within the range of 0.9 to 1.5 nm and a length within the range of 700 nm to 1.5 μm.

### (Evaluation)

The change in resistance value when the temperature of the infrared sensor produced in step 4 was changed from 20° C. to 40° C. was measured. The results showed that the TCR value (dR/RdT) was about −10.5%/K at 300K. It was found that this value largely exceeds that of Comparative Example 1 and −2%/K of the conventionally used vanadium oxide. This is not only because semiconducting carbon nanotubes in the bolometer thin film had a small diameter and a large band gap, but also because the negative thermal expansion material gradually reduced in volume with the temperature rising, resulting the increase of the density of the bolometer thin film, and the number of conductive paths between carbon nanotubes was gradually increased.

### Example 2

Negative thermal expansion material (BiNi_{0.85}Fe_{0.15}O₃, thermal expansion coefficient: about −180 ppm/K, resistivity: 5 Ωcm, shape: spherical) was mixed to the semiconducting carbon nanotube dispersion liquid, which is same as that of steps 1 to 2 of Example 1, so that the ratio by weight of the semiconducting carbon nanotubes was 60%. A dispersion liquid of semiconducting carbon nanotubes/negative thermal electrical material was prepared by ultrasonic treatment.

### (Step 4)

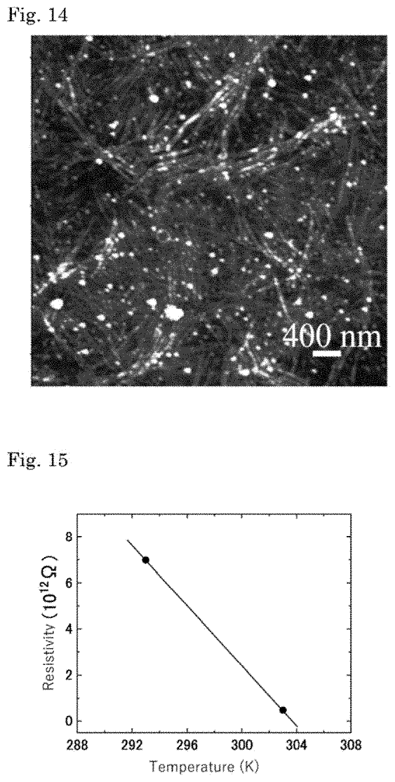

A substrate in which a silicon substrate is coated with 100 nm of SiO₂ was prepared. The substrate was washed, and immersed in a 0.1% APTES aqueous solution for 30 minutes. After washing, the substrate was dried at 105° C. A dispersion liquid of semiconducting carbon nanotubes/negative electrical material was added dropwise on the obtained substrate, and dried at 110° C. The substrate was heated in an air atmosphere at 180° C. to remove the nonionic surfactant and the like. Thereafter, gold was vapor deposited to a thickness of 200 nm at two positions on the substrate at an interval of 100 μm. Then, a PMMA anisole solution was applied between the electrodes to protect the carbon nanotubes between the electrodes, and then, excess carbon nanotubes and the like near the electrodes were removed by oxygen plasma treatment. Thereafter, the substrate was dried at 180° C. for one hour to produce an infrared sensor. FIG. 14 is the AFM image of the obtained bolometer thin film. The fibrous structures are carbon nanotubes and the spherical particles are the thermal expansion material. It can be seen that the thermal expansion material is uniformly adsorbed on the carbon nanotubes. The diameter was evaluated in the radial breathing mode (RBM) of Raman spectra and was estimated to be between 0.9 and 1.5 nm.

### (Evaluation)

The change in resistance value at 0.6 V when the temperature of the infrared sensor produced in step 4 was changed from 293K to 303K was measured (FIG. 15). The results showed that the TCR value (dR/RdT) was about −9.3%/K at 293K. It was found that this value was much higher than Comparative Example 1 or −2%/K of the conventionally used vanadium oxide.

### Example 3

Negative thermal expansion material (Mn_{3.27}Sn_{0.28}Zn_{0.45}N, thermal expansion coefficient: about −40 ppm/K, resistivity: 0.3 Ωcm, shape: spherical) was mixed to the semiconducting carbon nanotube dispersion liquid, which is same as that of steps 1 to 2 of Example 1, so that the ratio by weight of the semiconducting carbon nanotubes was 60%. A dispersion liquid of semiconducting carbon nanotubes/negative thermal electrical material was prepared by ultrasonic treatment.

### (Step 4)

A substrate in which a silicon substrate is coated with 100 nm of SiO₂ was prepared. The substrate was washed, and immersed in a 0.1% APTES aqueous solution for 30 minutes. After washing, the substrate was dried at 105° C. A semiconducting carbon nanotubes/negative thermal electrical material dispersion liquid was added dropwise on the obtained substrate, and dried at 110° C. The substrate was heated in an air atmosphere at 180° C. to remove the nonionic surfactant and the like. Thereafter, gold was vapor deposited to a thickness of 200 nm at two positions on the substrate at an interval of 100 μm. Then, a PMMA anisole solution was applied between the electrodes to protect the carbon nanotubes between the electrodes, and then, excess carbon nanotubes and the like near the electrodes were removed by oxygen plasma treatment. Thereafter, the substrate was dried at 180° C. for one hour to produce an infrared sensor.

### (Evaluation)

The change of resistance at 0.6V when the temperature of the infrared sensor manufactured in step 4 was changed from 293K to 303K was measured. The resulted TCR value (dR/RdT) was about −6.4%/K at 293K. This value was higher than Comparison example 1. The TCR value was lower as compared to Examples 1 and 2. This may be due to the slight solubility of MnₓSn_{y}Zn_{z}N in water, and the negative expansion effect may not be sufficiently obtained due to the dissolution of the particles during the ink preparation process.

### Comparative Example 1

An infrared sensor was produced using a semiconducting carbon nanotube dispersion liquid in the same manner as in step 1 of Example 1 and in the same manner as in step 4 except for not performing the mixing step in step 3. The TCR value at this time was about −5.5%/K. The TCR value is lower as compared to Example 1 because the conductive paths between carbon nanotubes do not change with respect to the temperature change.

The whole or part of the example embodiments disclosed above can be described as, but not limited to, the following supplementary notes.

### (Supplementary Note 1)

A bolometer material which is a thin film comprising semiconducting carbon nanotubes and a negative thermal expansion material.

### (Supplementary Note 2)

The bolometer material according to supplementary note 1, wherein the thin film comprising semiconducting carbon nanotubes and a negative thermal expansion material comprises the negative thermal expansion material in the semiconducting carbon nanotubes in an amount of from 1 to 99% by mass based on the total mass of the thin film.

### (Supplementary Note 3)

The bolometer material according to supplementary note 1 or 2, wherein the semiconducting carbon nanotubes have a semiconductor purity of 67% by mass, a diameter within the range of 0.6 to 1.5 nm and a length within the range of 100 nm to 5 μm.

### (Supplementary Note 4)

The bolometer material according to any one of supplementary notes 1 to 3, wherein the negative thermal expansion material is an oxide, a nitride, a sulphide or a multi-element compound comprising one or two or more selected from the group consisting of Fe, Ni, Co, Mn, Bi, La, Cu, Sn, Zn, V, Zr, Pb, Sm, Y, W, P, Ru, Ti, Ge, Ca, Ga, Cr and Cd, or a mixture thereof.

### (Supplementary Note 5)

The bolometer material according to supplementary note 4, wherein the negative thermal expansion material is one or more types of oxide.

### (Supplementary Note 6)

The bolometer material according to any one of supplementary notes 1 to 5, wherein the negative thermal expansion material has a coefficient of linear thermal expansion ΔL/L ((length after expansion−length before expansion)/length before expansion) per 1K ranging from −1×10⁻⁶/K to −1×10⁻³/K in a temperature range of from −100 to +100° C.

### (Supplementary Note 7)

The bolometer material according to any one of supplementary notes 1 to 6, wherein the resistivity of the negative thermal expansion material is in the range from 10⁻¹ Ωcm to 10⁸ Ωcm in a temperature range of from −100 to +100° C.

### (Supplementary Note 8)

An infrared sensor, comprising
a substrate;
a first electrode on the substrate;
a second electrode spaced from the first electrode on the substrate; and
the bolometer material according to any one of supplementary notes 1 to 7 electrically connected with the first electrode and the second electrode.

### (Supplementary Note 9)

An infrared sensor according to supplementary note 8, wherein the electrode distance between the first electrode and the second electrode is 10 μm to 500 μm.

### (Supplementary Note 10)

An infrared sensor, comprising
a substrate;
an infrared detection unit held on the substrate with a gap therebetween by a supporting leg,
wherein the infrared detection unit comprises a bolometer thin film comprising semiconducting carbon nanotubes and a negative thermal expansion material.

### (Supplementary Note 11)

The infrared sensor according to supplementary note 10, comprising no light reflection layer.

### (Supplementary Note 12)

An infrared sensor, comprising
a substrate;
a heat insulating layer formed on the substrate; and
a bolometer thin film formed on the heat insulating layer;
wherein the bolometer thin film comprises semiconducting carbon nanotubes and a negative thermal expansion material.

### (Supplementary Note 13)

The infrared sensor according to supplementary note 12, comprising no light reflection layer.

### (Supplementary Note 14)

The infrared sensor according to any one of claims 8 to 13, which is a bolometer array in which a plurality of elements comprising a bolometer thin film comprising semiconducting carbon nanotubes and a negative thermal expansion material are formed on a substrate.

### (Supplementary Note 15)

A method for manufacturing a bolometer material, comprising
mixing carbon nanotubes, a nonionic surfactant, and a dispersion medium to prepare a solution comprising carbon nanotubes;
subjecting the solution to dispersion treatment to disperse and cut the carbon nanotubes, thereby preparing a carbon nanotube dispersion liquid;
subjecting the carbon nanotube dispersion liquid to free flow electrophoresis to separate semiconducting carbon nanotubes and metallic carbon nanotubes, thereby preparing a semiconducting carbon nanotube dispersion liquid comprising semiconducting carbon nanotubes; and
mixing the semiconducting carbon nanotube dispersion liquid and a negative thermal expansion material to prepare a mixed liquid,
removing excess nonionic surfactant and dispersion medium from the mixed liquid to form a thin film in a desired form.

### (Supplementary Note 16)

A method for manufacturing an infrared sensor,

wherein the infrared sensor comprises
a substrate;
a first electrode on the substrate;
a second electrode spaced from the first electrode on the substrate; and
a bolometer material electrically connected with the first electrode and the second electrode, and
   wherein the method comprises
(a) applying the mixed liquid comprising the semiconducting carbon nanotube and the negative thermal expansion material on the substrate;
(b) subjecting the substrate on which the mixed liquid is applied to heat treatment; and
(c) producing the first electrode and the second electrode on the substrate before applying the mixed liquid on the substrate, or before or after subjecting the substrate on which the mixed liquid is applied to heat treatment,
   thereby connecting the first electrode and the second electrode by the bolometer material.

### (Supplementary Note 17)

A method for manufacturing an infrared sensor, comprising
forming an infrared detection unit on a substrate via a supporting leg;
forming a gap between the substrate and the infrared detection unit; and
forming a bolometer thin film comprising semiconducting carbon nanotubes and a negative thermal expansion material on the infrared detection unit.

### (Supplementary Note 18)

A method for manufacturing an infrared sensor, comprising
forming a heat insulating layer on a substrate, and
forming a thin film comprising semiconducting carbon nanotubes and a negative thermal expansion material on the insulating layer.

While the invention has been described with reference to example embodiments and examples thereof, the invention is not limited to these embodiments and examples. Various changes that can be understood by those of ordinary skill in the art may be made to form and details of the present invention without departing from the spirit and scope of the present invention.

This application claims priority based on PCT/JP2020/20795 filed on May 26, 2020 and Japanese patent application No. 2020-218851 filed on Dec. 28, 2020, the entire disclosures of which are incorporated herein.

### EXPLANATION OF REFERENCE

1 Bolometer film
2 Semiconducting carbon nanotube
3 Negative thermal expansion material
4 Electrode 1 (first electrode)
5 Electrode 2 (second electrode)
6 Substrate
101 Substrate
102 Gap
103 Electrode
104 Bolometer film
105 Wiring
106 Supporting leg
107 Infrared absorbing layer/Infrared absorbing structure
108 Protection layer (insulating protection layer)
109 Light reflection layer (infrared reflection layer)
110 Infrared detection unit
111 Row wiring
112 Column wiring
113 Readout circuit
114 Incident light
115 Light transmitted through a bolometer film
201 Substrate
202 Heat insulating layer
203 Electrode
204 Bolometer film
205 Contact
206 Column wiring
207 Row wiring
208 Protection layer
209 Infrared absorbing layer
210 Light reflection layer
211 Insulating film
212 First substrate
213 Second substrate
214 Column terminal
215 Row terminal
216 Column selecting circuit
217 Row selecting circuit
218 Bonding wire
219 Gate electrode
220 Source electrode
221 Semiconductor
222 Drain electrode
223 Via
224 Common electrode
225 Source line
226 Gate line

What is claimed is:

1. A bolometer material which is a thin film comprising semiconducting carbon nanotubes and a negative thermal expansion material.

2. The bolometer material according to claim 1, wherein the thin film comprising semiconducting carbon nanotubes and a negative thermal expansion material comprises the negative thermal expansion material in the semiconducting carbon nanotubes in an amount of from 1 to 99% by mass based on the total mass of the thin film.

3. The bolometer material according to claim 1, wherein the semiconducting carbon nanotubes have a semiconductor purity of 67% by mass, a diameter within the range of 0.6 to 1.5 nm and a length within the range of 100 nm to 5 μm.

4. The bolometer material according to claim 1, wherein the negative thermal expansion material is an oxide, a nitride, a sulphide or a multi-element compound comprising one or two or more selected from the group consisting of Li, Al Fe, Ni, Co, Mn, Bi, La, Cu, Sn, Zn, V, Zr, Pb, Sm, Y, W, Si, P, Ru, Ti, Ge, Ca, Ga, Cr and Cd, or a mixture thereof.

5. The bolometer material according to claim 4, wherein the negative thermal expansion material is one or more types of oxide.

6. The bolometer material according to claim 1, wherein the negative thermal expansion material has a coefficient of linear thermal expansion ΔL/L ((length after expansion−length before expansion)/length before expansion) per 1K ranging from −1×10⁻⁶/K to −1×10⁻³/K in a temperature range of from −100 to +100° C.

7. The bolometer material according to claim 1, wherein the resistivity of the negative thermal expansion material is in the range from 10⁻¹ Ωcm to 10⁸ Ωcm in a temperature range of from −100 to +100° C.

8. An infrared sensor comprising
a substrate;
a first electrode on the substrate;
a second electrode spaced from the first electrode on the substrate; and
the bolometer material according to claim 1 electrically connected with the first electrode and the second electrode.

9. An infrared sensor according to claim 8, wherein the electrode distance between the first electrode and the second electrode is 10 μm to 500 μm.

10. An infrared sensor comprising
a substrate;
an infrared detection unit held on the substrate with a gap therebetween by a supporting leg,
wherein the infrared detection unit comprises the bolometer material according to claim 1.

11. The infrared sensor according to claim 10, comprising no light reflection layer.

12. An infrared sensor comprising
a substrate;
a heat insulating layer formed on the substrate; and
the bolometer material according to claim 1 formed on the heat insulating layer.

13. The infrared sensor according to claim 12, comprising no light reflection layer.

14. The infrared sensor according to claim 8, which is a bolometer array in which a plurality of elements comprising a bolometer thin film comprising semiconducting carbon nanotubes and a negative thermal expansion material are formed on a substrate.

15. A method for manufacturing a bolometer material, comprising
mixing carbon nanotubes, a nonionic surfactant, and a dispersion medium to prepare a solution comprising carbon nanotubes;
subjecting the solution to dispersion treatment to disperse and cut the carbon nanotubes, thereby preparing a carbon nanotube dispersion liquid;
subjecting the carbon nanotube dispersion liquid to free flow electrophoresis to separate semiconducting carbon nanotubes and metallic carbon nanotubes, thereby preparing a semiconducting carbon nanotube dispersion liquid comprising semiconducting carbon nanotubes; and
mixing the semiconducting carbon nanotube dispersion liquid and a negative thermal expansion material to prepare a mixed liquid,
removing excess nonionic surfactant and dispersion medium from the mixed liquid to form a thin film in a desired form.

16. A method for manufacturing an infrared sensor,
wherein the infrared sensor comprises
a substrate;
a first electrode on the substrate;
a second electrode spaced from the first electrode on the substrate; and
a bolometer material electrically connected with the first electrode and the second electrode, and
wherein the method comprises
(a) applying the mixed liquid comprising the semiconducting carbon nanotube and the negative thermal expansion material on the substrate;
(b) subjecting the substrate on which the mixed liquid is applied to heat treatment; and
(c) producing the first electrode and the second electrode on the substrate before applying the mixed liquid on the substrate, or before or after subjecting the substrate on which the mixed liquid is applied to heat treatment,
thereby connecting the first electrode and the second electrode by the bolometer material.

17-18. (canceled)
